(19) United States
(12) Patent Application Publication
(10) Pub. No.: US 2008/0050186 A1
(43) Pub. Date: Feb. 28, 2008

(54) Cemented carbide inserts for milling of hard fe-based alloys more than 45 HRC

(75) Inventors: Kenneth Westergren, Hagersten (SE); Susanne Norgren, Stockholm (SE)

Correspondence Address: DRINKER BIDDLE & REATH (DC), 1500 K STREET, N.W., SUITE 1100, WASHINGTON, DC, 20005-1209, US

(73) Assignee: SANDVIK INTELLECTUAL PROPERTY AB

(21) Appl. No.: 11/892,555

(22) Filed: Aug. 23, 2007

(30) Foreign Application Priority Data
Aug. 28, 2006 (SE) 0601759-4

(51) Int. Cl. B32B 33/00; B23C 5/00; C23C 14/14

(52) U.S. Cl. 407/119; 427/531

(57) ABSTRACT

The present invention relates to cutting insert for milling of hardened steels, tool steels and hard cast irons and stainless steels with a hardness of more than about 45 HRC comprising a substrate and a coating. The substrate has a hardness of from about 1700 HV3 to about 2000 HV3, with a 10° angle and 0.2 mm wide negative chamfer giving an edge sharpness of 0(sharp) to about 40 μm and the coating comprises a homogeneous AlₓTi₁₋ₓN-layer with x=from about 0.6 to about 0.67, preferably x=about 0.62 and a thickness of more than about 1 to less than about 3.8 μm. The invention also relates to a method of making as well as the use of the inserts.

### BACKGROUND OF THE INVENTION

The present invention relates to a coated cutting tool insert particularly useful for milling of hard cast irons and hardened steels. A thin PVD-coating greatly improves the flank wear resistance and the notch wear resistance combined with a substrate that provides good resistance against plastic deformation, comb cracks and edge line chipping.

Milling of hard cast irons and hardened steels can generally be divided in roughing, semi-roughing, semi-finishing and finishing. In milling hardened steel, hard steels, tool steels and cast irons edge line chipping and notch wear is one of the dominant wear mechanisms.

### OBJECTS AND SUMMARY OF THE INVENTION

It is an object of the present invention to provide a cutting tool insert particularly useful for milling hard cast irons, hard steels, tool steels and hardened steels.

It is a further object of the present invention to provide a cutting tool insert with improved edge line security, wear resistance in combination with good plastic deformation resistance.

In another aspect of the invention, there is provided a cutting tool insert comprising a substrate and a coating wherein said substrate has a hardness of from about 1700 HV3 to about 2000 HV3, with a 10° angle and 0.2 mm wide negative chamfer giving an edge sharpness of 0(sharp) to about 40 μm and said coating comprises a homogeneous AlₓTi₁₋ₓN-layer with x=from about 0.6 to about 0.67, and has a total thickness of more than about 1 μm, but less than about 3.8 μm.

In a still further aspect of the invention, there is provided a method of making a cutting tool insert of a cemented carbide substrate and a coating whereby the substrate is made using conventional powder metallurgical techniques of milling, pressing and sintering, said substrate having a hardness of from about 1700 HV3 to about 2000 HV3, with a 10° angle and 0.2 mm wide negative chamfer giving an edge sharpness of 0(sharp) to about 40 μm and the coating comprises AlₓTi₁₋ₓN with x=from about 0.6 to about 0.67, deposited by cathodic arc evaporation using a target material of TiAl-alloy of suitable composition, in an N₂ gas atmosphere whereby the total thickness of the coating is more than about 1 μm, but less than about 3.8 μm.

In a still further aspect of the invention, there is provided a use of the insert described above for milling of hardened steels more than about 45 HRC and hard cast irons at a cutting speed of from about 30 to about 180 m/min and a feed of from about 0.1 to about 0.4 mm/rev.

### DETAILED DESCRIPTION OF THE PREFERRED EMBODIMENTS

It has now surprisingly been found that a hard cubic carbide containing cemented carbide substrate combined with a relatively thin PVD-coating in combination with a special edge treatment giving a sharp edge greatly improves the edge line security, and wear resistance in addition to good resistance against plastic deformation resulting in increased tool life and surface quality on the workpiece surfaces when milling in hardened steels and hard cast irons with hardness more than about 45 HRC.

The substrate comprises a cemented carbide with a hardness of from about 1700 HV3 to about 2000 HV3, preferably with the composition from about 5.4 to about 6.3 wt-% Co, preferably from about 5.7 to about 6.1 wt-% Co, from about 0.7 to about 1.0 wt-% Ta+Nb, preferably from about 0.6 to about 0.95 wt-% Ta+Nb, most preferably from about 0.7 to about 0.9 wt-% Ta+Nb, and from about 5.0 to about 7.0 wt-% Ti, preferably from about 5.5 to about 6.5 wt-% Ti, most preferably from about 6.0 to about 6.4 wt-% Ti, added as TaC, NbC and TiC or mixtures of these, and balance WC with as sintered Hc-value of from about 20 to about 26, preferably from about 21 to about 25, kA/m.

The cobalt binder phase is alloyed with W giving the invented cemented carbide cutting insert its desired properties. W in the binder phase influences the magnetic properties of cobalt and can hence be related to a value, CW-ratio, defined as

CW-ratio=magnetic-% Co/wt-% Co

where magnetic-% Co is the weight percentage of magnetic Co and wt-% Co is the weight percentage of Co in the cemented carbide.

The CW-ratio varies between 1 and about 0.75 dependent on the degree of W-alloying. Lower CW-ratios correspond to higher W and CW=1 corresponds practically to an absence of W in the binder phase. The cemented carbide body according to the invention has a CW-ratio from about 0.75 to about 0.95, preferably from about 0.78 to about 0.90.

The uncoated substrates have a 10° angle and 0.2 mm wide negative chamfer giving an edge sharpness of 0(sharp) to about 40 μm.

The coating comprises a homogeneous AlₓTi₁₋ₓN-layer with x=from about 0.6 to about 0.67, preferably x=about 0.62. The total thickness of the layer is more than about 1 μm, preferably more than about 1.8 μm, but less than about 3.8 μm, preferably less than about 3.0 μm. Both the composition and the thickness are determined on the flank face 1 mm from the nose radius and 200 μm from the cutting edge.

The present invention also relates to a method of making a coated cutting tool insert consisting of a cemented carbide substrate and a coating. The cemented carbide substrate has before coating a 10° angle and 0.2 mm wide negative chamfer giving an edge sharpness of 0(sharp) to about 40 μm and is made using conventional powder metallurgical techniques milling, pressing and sintering.

The substrate comprises a cemented carbide with a hardness of from about 1700 HV3 to about 2000 HV3, preferably with the composition from about 5.4 to about 6.3 wt-% Co, preferably from about 5.7 to about 6.1 wt-% Co, from about 0.7 to about 1.0 wt-% Ta+Nb, preferably from about 0.6 to about 0.95 wt-% Ta+Nb, most preferably from about 0.7 to about 0.9 wt-% Ta+Nb, and from about 5.0 to about 7.0 wt-% Ti, preferably from about 5.5 to about 6.5 wt-% Ti, most preferably from about 6.0 to about 6.4 wt-% Ti, added as TaC, NbC and TiC or mixtures of these, and balance WC with as sintered Hc-value of from about 20 to about 26, preferably from about 21 to about 25 kA/m.

After conventional post sintering treatment a coating comprising AlₓTi₁₋ₓN with x=from about 0.6 to about 0.67, preferably x=about 0.62 is deposited by cathodic arc evaporation using a target material consisting of TiAl-alloy of suitable composition, in an N₂ gas atmosphere. The total thickness of the coating is more than about 1 μm, preferably more than about 1.8 μm, but less than about 3.8 μm, preferably less than about 3.0 μm.

The present invention also relates to the use of the insert described above for milling in hard steels, tool steels, hardened steels and hard cast irons with hardness more than about 45 HRC at a cutting speed of from about 50 to about 180 m/min and a feed of from about 0.1 to about 0.4 mm/rev.

The invention is additionally illustrated in connection with the following examples, which are to be considered as illustrative of the present invention. It should be understood, however, that the invention is not limited to the specific details of the examples.

### EXAMPLE 1

A. Cemented carbide milling inserts in accordance with the invention with the composition 5.90 wt-% Co, 0.56 wt-% Ta, 0.35 wt-% Nb, 6.16 wt-% Ti added as TaC, NbC and TiC and balance WC with as sintered Hc-value of 23 kA/m and with a binder phase alloyed with W corresponding to a CW-ratio of 0.86 were coated with a 2.9 μm homogeneous Al_{0.62}Ti_{0.38}N-PVD-layer by cathodic arc evaporation using a target material consisting of a Ti₃₃Al₆₇-alloy. The arc evaporation was performed in an N₂ gas atmosphere.

B. (Reference) Commercial cemented carbide milling inserts with the composition of 3.70 wt-% Co, 1.43 wt-% Ta, 0.42 wt-% Nb and balance WC and with an Hc-value of 23 kA/m and a CW-ratio of 0.9. The inserts were coated with a 2.9 μm (Ti,Al)N PVD-coating as in A.

### EXAMPLE 2

Inserts from A and B were tested in turning of a cast steel.

| | |
|---|---|
| Operation: | Side long edge milling |
| Work-piece: | Stator and rotator segment |
| Material: | Austenitic steel with carbides, C = 1.15 |
| | Hardness 55-58 HRC |
| Cutting speed: | 125 m/min (n = 500) |
| Feed rate: | 700 mm/min (fz = 0.28) |
| Depth of cut: | Radial Aₑ = 1-2 mm; axial Aₚ = 50-70 mm |
| Insert-style: | SECT120612 T02010 |
| Note: | Dry milling |

Criteria for replacing inserts: edge line chipping and/or risk of insert breakage.

Results:

| | |
|---|---|
| Grade A: (invention) | 21 segments |
| Grade B: (prior art) | 15 segments |

### EXAMPLE 3

Inserts from A and B were tested in milling of a cast steel.

| | |
|---|---|
| Operation: | Side long edge milling |
| Work-piece: | Stator and rotator segment |
| Material: | Austenitic tool steel |
| | Hardness 60 HRC |
| Cutting speed: | 85 m/min (n = 340) |
| Feed rate: | 320 mm/min (fz = 0.19) |
| Depth of cut: | Radial Aₑ = 1-2 mm; axial Aₚ = 50-70 mm |
| Insert-style: | SECT120612 T02010 |
| Note: | Dry milling |

Criteria for replacing inserts: edge line chipping and/or risk of insert breakage.

Results:

| | |
|---|---|
| Grade A: (invention) | 8 segments (H1P) |
| Grade B: (prior art) | 2 segments (H05) |

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

1. Cutting tool insert comprising a substrate and a coating wherein
said substrate has a hardness of from about 1700 HV3 to about 2000 HV3, with a 10° angle and 0.2 mm wide negative chamfer giving an edge sharpness of 0(sharp) to about 40 μm and
said coating comprises a homogeneous AlₓTi₁₋ₓN-layer with x=from about 0.6 to about 0.67, and has a total thickness of more than about 1 μm, but less than about 3.8 μm.

2. A cutting tool insert of claim 1 wherein the substrate has a composition from about 5.4 to about 6.3 wt-% Co, from about 0.7 to about 1.0 wt-% Ta+Nb, and from about 5.0 to about 7.0 wt-% Ti, added as TaC, NbC and TiC or mixtures of these, and balance WC with an as sintered Hc-value of from about 20 to about 26, kA/m and CW from about 0.75 to about 0.95.

3. A cutting tool insert of claim 1 wherein in said coating, x is about 0.62 and said layer has a total thickness of more than about 1.8 to less than about 3.0 μm.

4. A cutting tool insert of claim 2 wherein said substrate has a composition of from about 5.7 to about 6.1 wt-% of Co, from about 0.6 to about 0.95 wt-% of Ta+Nb and from about 5.5 to about 6.5 wt-% Ti.

5. A cutting tool insert of claim 4 wherein said substrate has a composition of from about 0.7 to about 0.9 wt-% Ta+Nb and from about 6.0 to about 6.4 wt-% Ti.

6. A cutting tool insert of claim 2 wherein said substrate has a sintered Hc-value of from about 21 to about 25 and a CW of from about 0.78 to about 0.90.

7. Method of making a cutting tool insert of a cemented carbide substrate and a coating whereby the substrate is made using conventional powder metallurgical techniques of milling, pressing and sintering, said substrate having a hardness of from about 1700 HV3 to about 2000 HV3, with a 10° angle and 0.2 mm wide negative chamfer giving an edge sharpness of 0(sharp) to about 40 μm and
the coating comprises AlₓTi₁₋ₓN with x=from about 0.6 to about 0.67, deposited by cathodic arc evaporation using a target material of TiAl-alloy of suitable composition, in an N₂ gas atmosphere whereby the total thickness of the coating is more than about 1 μm, but less than about 3.8 μm.

8. Method according to claim 7 wherein the substrate has a composition from about 5.4 to about 6.3 wt-% Co, from about 0.7 to about 1.0 wt-% Ta+Nb, and from about 5.0 to about 7.0 wt-% Ti, added as TaC, NbC and TiC or mixtures of these, and balance WC with an as sintered Hc-value of from about 20 to about 26, and a CW of from about 0.75 to about 0.95.

9. Method according to claim 7 wherein in said coating, x is about 0.62 and said layer has a total thickness of more than about 1.8 to less than about 3.0 μm.

10. Method according to claim 8 wherein said substrate has a composition of from about 5.7 to about 6.1 wt-% of Co, from about 0.6 to about 0.95 wt-% of Ta+Nb and from about 5.5 to about 6.5 wt-% Ti.

11. Method of claim 10 wherein said substrate has a composition of from about 0.7 to about 0.9 wt-% Ta+Nb and from about 6.0 to about 6.4 wt-% Ti.

12. Method of claim 8 wherein said substrate has a sintered Hc-value of from about 21 to about 25 and a CW of from about 0.78 to about 0.90.

13. Use of the insert according to claim 1 for milling of hardened steels more than about 45 HRC and hard cast irons at a cutting speed of from about 30 to about 180 m/min and a feed of from about 0.1 to about 0.4 mm/rev.
